(19) United States
(12) Patent Application Publication
(10) Pub. No.: US 2024/0326384 A1
(43) Pub. Date: Oct. 3, 2024

(54) OPTICAL LAMINATE, TRANSPARENT DISPLAY INCLUDING SAME, AND METHOD FOR MANUFACTURING SAME

(71) Applicant: DONGWOO FINE-CHEM CO., LTD., Iksan-si (KR)

(72) Inventors: Sung-Jin NOH, Iksan-si (KR); Goo-Hyun KANG, Iksan-si (KR); Sang-Won YUN, Iksan-si (KR); Jun-Gu LEE, Iksan-si (KR); Ki-Joon PARK, Iksan-si (KR); Cheol-Hun LEE, Iksan-si (KR)

(21) Appl. No.: 18/610,203

(22) Filed: Mar. 19, 2024

(30) Foreign Application Priority Data
Mar. 30, 2023 (KR) 10-2023-0042198
Feb. 16, 2024 (KR) 10-2024-0022417

(51) Int. Cl. B32B 17/06; B32B 7/12; B32B 15/20; B32B 37/12; B32B 38/10; H01L 25/13

(52) U.S. Cl. CPC B32B 17/061; B32B 7/12; B32B 15/20; B32B 37/12; B32B 38/10; H01L 25/13; B32B 2255/06; B32B 2255/26; B32B 2255/28; B32B 2307/414; B32B 2307/538; B32B 2311/12; B32B 2315/08; B32B 2457/20

(57) ABSTRACT

The present disclosure relates to an optical laminate including: a glass substrate; a pressure-sensitive adhesive layer formed on one surface of the glass substrate; a metal layer pattern formed on one surface of the pressure-sensitive adhesive layer; and a functional layer provided on a portion on one surface of the pressure-sensitive adhesive layer on which the metal layer pattern is not formed, wherein the pressure-sensitive adhesive layer contains a silicone-based pressure-sensitive adhesive, and the functional layer includes a solder resist layer, and a method for manufacturing the optical laminate.

### TECHNICAL FIELD

The present disclosure relates to an optical laminate, a transparent display including the same, and a method for manufacturing the same.

### BACKGROUND ART

Recently, the demand for large-area display devices according to advancement in technology in the display market is gradually increasing. Technology development is also gradually being made in the advanced electronic circuit and display business fields such as Micro-LED and Mini-LED, which can each adjust the contrast and brightness of unit area, and photolithography methods for manufacturing electronic devices for simultaneously satisfying high resolution and contrast ratio quality together with large-area sizes are being studied.

Korean Patent Publication No. 10-2019-0003025 also discloses a circuit board using a method of patterning a metal layer on the top of a glass substrate and a method for manufacturing the same.

However, various methods, such as plating or deposition of metal thin films, have been used as a method of implementing low-resistance metal wiring on conventional glass substrates, but each of these methods has limitations due to large-area of displays.

To overcome these limitations, attempts have recently been made to develop a technology for bonding a metal thin film to a glass substrate and then patterning the metal thin film using a photolithography method.

However, in such a method of bonding a metal thin film to a glass substrate, there have been problems in that not only adhesive force between the metal thin film and the glass substrate is not sufficient, but also the lower pressure-sensitive adhesive layer revealed after patterning the metal layer is damaged due to contact with the metal etchant.

Furthermore, especially when used in electronic devices exposed to the external environment for a long time, such as transparent displays, heat resistance and reliability in high temperature and high humidity environments are very important. However, in the case of acrylic pressure-sensitive adhesives or epoxy-based pressure-sensitive adhesives used in conventional metal thin films, there has been a problem in that heat resistance, or reliability in high temperature and high humidity environments is not sufficient.

In order to solve this problem, when a metal thin film is bonded to a glass substrate using a silicone-based pressure-sensitive adhesive, the metal surface shape that has been laminated remains on the peeled pressure-sensitive adhesive layer surface as it is after patterning of the metal thin film, thereby generating irregularities (roughness) on the surface. Accordingly, when applied to a display, light is scattered on the surface of the pressure-sensitive adhesive layer on which the metal thin film pattern is not formed, increasing haze so that there is a problem in that visibility is reduced.

Accordingly, there is a need for the development of optical laminates and transparent displays having improved visibility as well as improved adhesive force to a glass substrate, chemical resistance to metal layer etchants, heat resistance, and reliability in high temperature and high humidity environments.

### DISCLOSURE

### Technical Problem

An object of the present disclosure is to provide an optical laminate and a transparent display, in which visibility is improved by reducing haze of the surface, in an optical laminate that not only has excellent adhesive force to a glass substrate, but also has excellent chemical resistance to etchants, heat resistance, and reliability.

Further, another object of the present disclosure is to provide a method for manufacturing the optical laminate and the transparent display.

### Technical Solution

The present disclosure relates to an optical laminate including: a glass substrate; a pressure-sensitive adhesive layer formed on one surface of the glass substrate; a metal layer pattern formed on one surface of the pressure-sensitive adhesive layer; and a functional layer provided on a portion on one surface of the pressure-sensitive adhesive layer on which the metal layer pattern is not formed, wherein the pressure-sensitive adhesive layer contains a silicone-based pressure-sensitive adhesive, and the functional layer includes a solder resist layer.

In the first aspect of the present disclosure, the functional layer may be provided to cover the entirety or a portion of the metal layer pattern.

In the second aspect of the present disclosure, the metal layer may have a thickness of 3 μm to 120 μm.

In the third aspect of the present disclosure, the metal layer may contain one or more selected from the group consisting of copper (Cu), aluminum (Al), nickel (Ni), chromium (Cr), silver (Ag), iron (Fe), gold (Au), cobalt (Co), titanium (Ti), and tungsten (W).

In the fourth aspect of the present disclosure, the pressure-sensitive adhesive layer may have a thickness of 5 μm to 50 μm.

In the fifth aspect of the present disclosure, the optical laminate may not include a separate member between the metal layer and the pressure-sensitive adhesive layer.

In the sixth aspect of the present disclosure, the pressure-sensitive adhesive layer may have an adhesive force with a glass substrate of 5B or more.

The present disclosure relates to a transparent display including the optical laminate and light emitting diodes (LEDs).

In the seventh aspect of the present disclosure, the transparent display may further include a transparent cover at the outermost portion corresponding to the glass substrate of the optical laminate.

In the eighth aspect of the present disclosure, the transparent cover may be one or more selected from glass, wired sheet glass, colored glass, magic mirror, and holographic glass.

In the ninth aspect of the present disclosure, when the transparent cover is glass, it may further include one or more selected from wired sheet glass, colored glass, magic mirror, and holographic glass.

Furthermore, the present disclosure relates to a method for manufacturing an optical laminate, including steps of: preparing a metal thin film including a silicone-based pressure-sensitive adhesive layer formed on one surface of a metal layer, and including a first protective film provided on one surface of the silicone-based pressure-sensitive adhesive layer and a second protective film provided on the other surface of the metal layer; peeling off the first protective film of the metal thin film; bonding the metal thin film so that the pressure-sensitive adhesive layer is disposed on one surface of a glass substrate; peeling off the second protective film of the metal thin film; patterning the metal layer to form a metal layer pattern; and forming a functional layer on a portion where the metal layer pattern is not formed, wherein the functional layer includes a solder resist layer.

In the tenth aspect of the present disclosure, the step of forming the metal layer pattern may include steps of: forming a photoresist pattern on one surface of the metal layer; etching an exposed region of the metal layer by the photoresist pattern; and peeling off the photoresist pattern.

In the eleventh aspect of the present disclosure, damage to the lower pressure-sensitive adhesive layer may not occur in the etching step.

### Advantageous Effects

The optical laminate and transparent display according to the present disclosure can obtain the effect of improving visibility by lowering surface roughness and reducing haze. In particular, the optical laminate and transparent display according to the present disclosure include a solder resist layer as a functional layer to suppress the generation of air bubbles within the structure of the optical laminate, thereby improving reliability and long-term storage reliability.

### DESCRIPTION OF DRAWINGS

FIG. 1 is a view showing an optical laminate according to one embodiment or a plurality of embodiments of the present disclosure.

FIG. 2 is a view showing a transparent display according to one embodiment or a plurality of embodiments of the present disclosure.

FIGS. 3A and 3B are views showing a method for manufacturing an optical laminate according to one embodiment of the present disclosure.

FIG. 3C relates to a method for manufacturing a transparent display according to one embodiment of the present disclosure, and is a view showing the step of mounting light emitting diodes (LEDs) 70.

### MODE FOR CARRYING OUT THE INVENTION

The present disclosure relates to an optical laminate and a transparent display, which have a pressure-sensitive adhesive layer containing a silicone-based pressure-sensitive adhesive, and a method for manufacturing the same, and has the effect of improving visibility by including a functional layer on the surface of the pressure-sensitive adhesive layer peeled off after patterning a metal thin film, and thus lowering surface roughness and reducing haze. In particular, the optical laminate and transparent display according to the present disclosure include a solder resist layer as a functional layer to suppress the generation of air bubbles within the structure of the optical laminate, thereby improving reliability and long-term storage reliability.

More specifically, the present disclosure relates to an optical laminate, including: a glass substrate; a pressure-sensitive adhesive layer formed on one surface of the glass substrate; a metal layer pattern formed on one surface of the pressure-sensitive adhesive layer; and a functional layer provided on a portion on one surface of the pressure-sensitive adhesive layer on which the metal layer pattern is not formed, wherein the pressure-sensitive adhesive layer contains a silicone-based pressure-sensitive adhesive, and the functional layer includes a solder resist layer, and a method for manufacturing the same.

Hereinafter, embodiments of the present disclosure will be described in more detail with reference to the drawings. However, the following drawings attached to this specification illustrate preferred embodiments of the present disclosure, and play a role of allowing the technical idea of the present disclosure together with the above-described contents of the invention to be further understood. Therefore, the present disclosure should not be construed as being limited only to the matters described in such drawings.

The terms used in this specification are for describing the embodiments and are not intended to limit the present disclosure. In this specification, singular forms also include plural forms unless specifically stated otherwise in the phrases. For example, ┌protective film┘ used in this specification may mean at least one protective film of a first protective film and a second protective film.

The term “comprises” and/or “comprising” used in this specification is used in the sense that it does not exclude the presence or addition of one or more other components, steps, operations and/or elements other than the stated component, step, operation and/or element. The same reference numerals refer to the same components throughout the specification.

Spatially relative terms ┌below┘, ┌bottom surface┘, ┌bottom portion┘, ┌above┘, ┌top surface┘, ┌top portion┘, etc. may be used to easily describe correlations of one element or components with another element or components as shown in the drawings. The spatially relative terms should be understood as terms including different directions of elements during use or operation in addition to the directions shown in the drawings. For example, when an element shown in the drawings is turned over, an element described as being ┌below┘ or ┌bottom portion┘ of other element may be placed ┌above┘ the other element. Accordingly, the exemplary term ┌below┘ may include both the below and above directions. Elements may also be oriented in other directions, and thus the spatially relative terms may be interpreted according to the orientation.

┌Substantially┘ used in this specification may be interpreted to include not only physically completely identical or matching, but also within the error range of measurement or manufacturing process, for example, an error range of 0.1% or less.

### <Optical Laminate and Transparent Display>

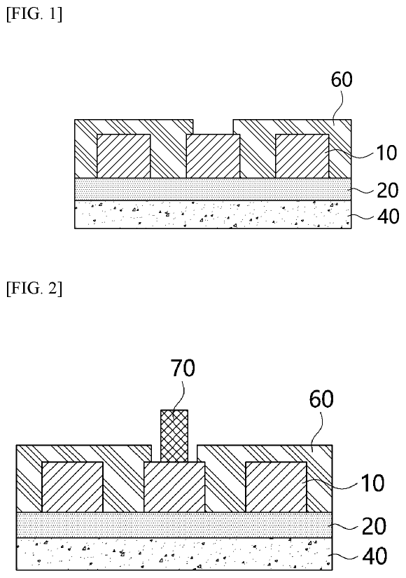

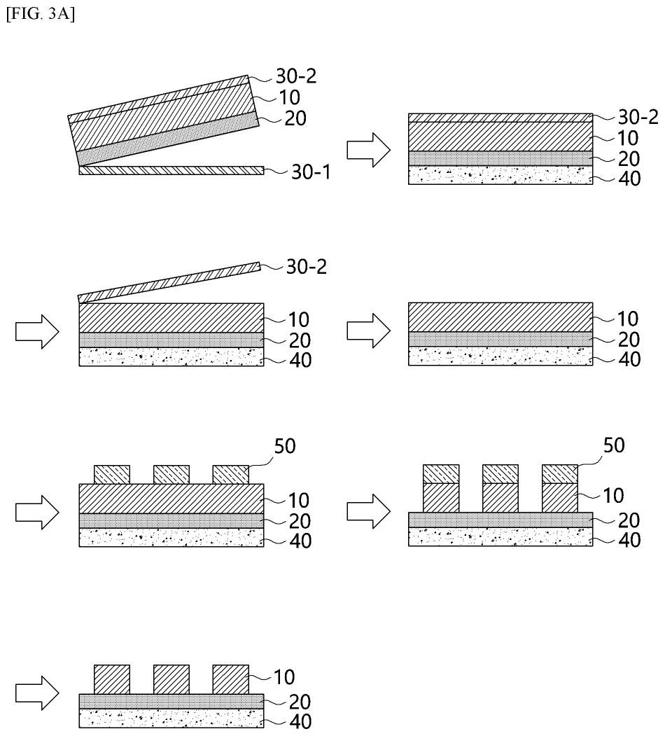

FIG. 1 is a view showing an optical laminate according to one embodiment or a plurality of embodiments of the present disclosure. In addition, FIG. 2 is a view showing a transparent display according to one embodiment or a plurality of embodiments of the present disclosure.

Referring to FIGS. 1 and 2, the optical laminate according to one embodiment or a plurality of embodiments of the present disclosure may include a glass substrate 40, a pressure-sensitive adhesive layer 20, a pattern of a metal layer 10, and a functional layer 60. In addition, the transparent display of the present disclosure may include the optical laminate and light emitting diodes (LEDs). In addition, the transparent display may further include a transparent cover, and may further include a transparent cover (not shown) at the outermost portion corresponding to the glass substrate of the optical laminate. The transparent cover may be one or more selected from glass, wired sheet glass, colored glass, magic mirror, and holographic glass. Further in the present disclosure, when the transparent cover is glass, it may further include one or more selected from wired sheet glass, colored glass, magic mirror, and holographic glass.

The glass substrate 40 is not particularly limited as long as it does not impair the optical properties of the optical laminate, and may include, for example, oxide glass and the like such as silicate glass, borate glass, and phosphate glass. In this case, there are advantages in that a heat shrinkage phenomenon or the like does not occur during subsequent processes, etc., and a predetermined hardness may be imparted to the optical laminate.

In one embodiment or a plurality of embodiments, the glass substrate 40 may have a thickness of 0.5 mm to 20 mm. When the thickness of the glass substrate 40 satisfies the above range, the glass substrate 40 enables thinning while having excellent hardness, and deformation or cracking occurred in the metal layer 10 can be prevented. Specifically, when the thickness of the glass substrate 40 is less than 0.5 mm, it may be difficult to protect the metal layer 10 or other laminated members from external shock, and when it exceeds 20 mm, it may be disadvantageous in terms of thinning or weight lightening.

In one embodiment or a plurality of embodiments, the glass substrate 40 may have a single-layered or multi-layered structure. For example, the glass substrate 40 may have a single-layered structure formed of a single glass substrate, but is not necessarily limited thereto, and may have a multi-layered structure in which a plurality of glass substrates are stacked.

In one embodiment, the optical laminate may include a pressure-sensitive adhesive layer 20 on one surface of the glass substrate 40.

The pressure-sensitive adhesive layer 20 may be manufactured from a pressure-sensitive adhesive layer composition comprising a silicone-based pressure-sensitive adhesive. The pressure-sensitive adhesive layer composition of the present disclosure may include a silicone-based additive and a solvent, and may further include an additive. Specifically, when a pressure-sensitive adhesive layer formed using a conventional acrylic pressure-sensitive adhesive or an epoxy-based pressure-sensitive adhesive is included, there has been a problem in that adhesive force to a glass substrate is not sufficient, or the pressure-sensitive adhesive layer is damaged by an etchant used to etch the metal layer formed on the top of the pressure-sensitive adhesive layer. Furthermore, when used in products that are mainly used outdoors, such as in the case of transparent displays, there has been a problem in that adhesive force of the pressure-sensitive adhesive layer to the glass substrate is reduced or yellowing of the pressure-sensitive adhesive layer occurs to cause product defects.

In order to solve such problems, the inventor of the present disclosure derived the present disclosure by taking notice of the point that, when the pressure-sensitive adhesive layer 20 contains a silicone-based pressure-sensitive adhesive, it not only has excellent adhesive force to the glass substrate, but also has excellent chemical resistance to etchants, and has excellent heat resistance and reliability in high temperature and high humidity environments.

The silicone-based pressure-sensitive adhesive may be one or more of a silicone compound and a siloxane compound.

The silicon compound may be used without particular limitation as long as it is a compound containing silicon (Si) atoms. In addition, a compound containing a siloxane bond of a Si—O bond may be used without limitation as the siloxane compound. More specifically, the silicon compound and the siloxane compound in one embodiment of the present disclosure may be one or more of trimethylated silica, vinyl terminated polydimethylsiloxane, hexamethyl di siloxane, trisiloxane, and tetrakis(trimethylsilyloxy)silane.

In particular, the silicone-based pressure-sensitive adhesive of the present disclosure is preferably contained in an amount of 40% to 60% of the total weight of the pressure-sensitive adhesive layer composition. As such, the silicone-based pressure-sensitive adhesive of the present disclosure may be diluted and added at a lower concentration than the conventional pressure-sensitive adhesive, and accordingly, when bonding the pressure-sensitive adhesive layer of the present disclosure to a metal layer or glass substrate, since adhesive force to the metal layer or glass substrate can be maximized, it has the advantage of enabling bonding even without additional treatment such as UV curing of the pressure-sensitive adhesive layer.

The solvent is not particularly limited as long as it can dilute the silicone-based pressure-sensitive adhesive, but examples thereof may include toluene, xylene, PGME, and/or PGMEA. The solvent of the present disclosure is preferably contained in an amount of 40% to 55% of the total weight of the pressure-sensitive adhesive layer composition in terms of stability of the pressure-sensitive adhesive coating thickness below the metal layer.

The additive may be one or more of an anchorage, a crosslinker, and a catalyst.

The anchorage is added for the purpose of increasing the bonding force with the metal layer when coating the pressure-sensitive adhesive layer, and can prevent the pressure-sensitive adhesive layer from being separated from the metal layer. Usually, there is no particular limitation as long as it is a material used as an anchorage, but it is preferable that thermal deformation does not occur at 200° C. or less.

The crosslinker is a material added for chemical bonding between components of the pressure-sensitive adhesive layer composition, and is preferably a product that does not undergo thermal deformation at 200° C. or less.

The catalyst is a component added to cure the pressure-sensitive adhesive layer composition and helps the pressure-sensitive adhesive layer composition to be transformed from a liquid phase to a solid phase. Specific examples thereof may include platinum catalysts, palladium catalysts, and/or osmium catalysts.

The additive of the present disclosure is preferably contained in an amount of 0.1% to 10% of the total weight of the pressure-sensitive adhesive layer composition in terms of adhesive force stability.

The pressure-sensitive adhesive layer 20 of the present disclosure may be formed by heating and curing the pressure-sensitive adhesive layer composition to a temperature of 100° C. to 180° C.

The pressure-sensitive adhesive layer 20 may have a thickness of 5 μm to 50 μm, preferably 5 μm to 30 μm, and more preferably 5 μm to 25 μm. When the thickness of the pressure-sensitive adhesive layer 20 is less than 5 μm, sufficient adhesive force to other members cannot be maintained, and when it exceeds 50 μm, there may be a disadvantage in terms of increased product thickness.

In one embodiment, the pressure-sensitive adhesive layer 20 may not include a separate member, for example, an intermediate layer or a protective layer, at the contact interface with the metal layer 10. Specifically, in the case of a pressure-sensitive adhesive layer formed using a conventional acrylic pressure-sensitive adhesive or an epoxy-based pressure-sensitive adhesive, there has been a problem in that the pressure-sensitive adhesive layer is damaged by the etchant used to etch the metal layer formed on the top of the pressure-sensitive adhesive layer as described above. For example, in the case of a pressure-sensitive adhesive layer formed using an epoxy-based pressure-sensitive adhesive, there has been a problem such as an increase in opacity of the pressure-sensitive adhesive layer upon contact with the etchant. Therefore, the conventional optical laminates separately included a member of an intermediate layer or protective layer between the pressure-sensitive adhesive layer and the metal layer in order to prevent damage to the pressure-sensitive adhesive layer by the etchant. However, when such a separate member is included, there have been problems in that not only the processability deteriorates and the manufacturing cost increases due to the addition of a manufacturing process, but also it is disadvantageous in terms of thin film manufacturing. However, in the present disclosure, since a pressure-sensitive adhesive layer is formed using a silicone-based pressure-sensitive adhesive having excellent chemical resistance to etchants as described above and thus occurrence of damage to the pressure-sensitive adhesive due to the etchant is prevented so that the member of the intermediate layer or protective layer conventionally provided to protect the pressure-sensitive adhesive is not separately included, not only is processability improved, but also there is an advantage in terms of reduction in manufacturing cost, and further there is an advantage also in terms of thinning of the film.

In one embodiment, the pressure-sensitive adhesive layer 20 may have an adhesive force to the glass substrate 40 of 5B or more. As described above, the pressure-sensitive adhesive layer 20 contains a silicone-based pressure-sensitive adhesive and is therefore characterized by having excellent adhesive force to the glass substrate 40.

In one embodiment, the adhesive force of the pressure-sensitive adhesive layer 20 to the glass substrate 40 may be evaluated by the measurement standard ISO 2409: Standard Test Methods for Measuring Adhesion by Tape Test.

The metal layer 10 may be used as an electrode in an electronic device such as a display device including the optical laminate.

The metal layer 10 is not particularly limited as long as it has electrical conductivity, and may include, for example, one or more selected from the group consisting of copper (Cu), aluminum (Al), nickel (Ni), chromium (Cr), silver (Ag), iron (Fe), gold (Au), cobalt (Co), titanium (Ti), and tungsten (W).

The metal layer 10 may be formed by a publicly-known metal thin film process, and it may be formed by, for example, preparing a metal thin film and attaching it thereto or using at least one method of electroless deposition, electrodeposition, sputtering, thermal evaporation, and E-beam evaporation, but the present disclosure is not limited thereto.

The metal layer 10 may have a thickness of 3 μm to 120 μm, preferably 3 μm to 110 μm, and more preferably 18 μm to 105 μm. When the thickness of the metal layer 10 is less than 3 μm, it may not be easy to form a uniform thin film or a pattern, and when it exceeds 120 μm, there may be a problem in that it cannot be applied to an electronic device with a thin film structure.

The functional layer 60 is formed on a portion on the pressure-sensitive adhesive layer 20 where the pattern of the metal layer 10 is not formed, that is, on the pressure-sensitive adhesive layer 20 exposed as the metal layer is etched during the formation of the pattern of the metal layer 10. The functional layer 60 may be formed by filling the portion where the pattern of the metal layer 10 is not formed as shown in FIG. 1, and more specifically, the functional layer 60 may be connected to a portion on the pressure-sensitive adhesive layer 20 where the metal layer 10 is not formed, and may also be formed in a form in which it is laminated on the metal layer 10.

More specifically, the functional layer may be formed to cover the entirety or a portion of the metal layer pattern. In one embodiment of the present disclosure, when there are a plurality of metal layer patterns, the functional layer may be formed to cover the entirety or only a portion of each metal layer pattern. More preferably, as shown in FIG. 1, the functional layer 60 is formed to completely cover some metal layer patterns (left and right of the three metal layer patterns 10 in FIG. 1), and it is preferably formed to only partially cover some metal layer patterns (middle of the three metal layer patterns 10 in FIG. 1). At this time, the metal layer pattern covered with only a portion of the functional pattern may be for mounting the light emitting diodes (LEDs) 70. In addition, the metal layer pattern entirely covered with the functional pattern can function as wiring. In this way, when the functional layer is formed to cover only a portion of the metal layer pattern, the extent to which the functional layer is formed on the metal layer pattern is not particularly limited as long as it is suitable for mounting the light emitting diodes (LEDs) 70.

Meanwhile, as described above, a metal layer 10 is laminated on one surface of the pressure-sensitive adhesive layer 20 of the present disclosure, and the metal layer 10 may have a surface roughness (Rz) of 0.1 to 20 μm.

At this time, the pressure-sensitive adhesive layer 20 includes a silicone-based pressure-sensitive adhesive layer, and thus the surface shape of the metal layer 10 is reflected in the pressure-sensitive adhesive layer 20 as it is. Therefore, when the metal layer 10 is peeled off after patterning, the surface of the pressure-sensitive adhesive layer 20 exposed by etching the metal layer generates irregularities derived from the metal layer having a certain surface roughness, and due to this, there are problems in that scattering of light occurs when applied to a transparent display, and haze increases.

Accordingly, the functional layer 60 may be provided in the portion of the pressure-sensitive adhesive layer 20 where the pattern of the metal layer 10 is not formed to prevent surface irregularities of the pressure-sensitive adhesive layer 20 from appearing, thereby preventing diffuse reflection and reducing haze to improve visibility.

In such an aspect, the functional layer 60 may have a surface roughness (Rz) of 5.0 μm or less. If the surface roughness (Rz) exceeds 5.0 μm, diffuse reflection occurs so that there are problems in that haze increases, and visibility is blurred.

The functional layer 60 may include a solder resist layer. Accordingly, it not only can reduce the transmittance and haze, but also suppress the generation of air bubbles within the structure of the optical laminate, thereby improving reliability and long-term storage reliability. More specifically, the functional layer 60 may be formed by a solder resist. The solder resist may be formed by any one of thermal curing, photo curing, and thermal/photo curing, and may also be any one of a liquid type and a film type.

When the solder resist is a liquid type, it may be manufactured from a solder resist composition containing a binder resin, a photopolymerizable compound, a photopolymerization initiator, a pigment, a dye, a solvent, and/or other additives.

When the solder resist is a liquid type, since printing and drying processes should be repeated during manufacturing, it is more preferable to apply the film type described later in the present disclosure.

When the solder resist is a film type, it may include a protective film, a photosensitive resin layer, and a base film. The base film includes a polyester film such as polyethylene terephthalate and is used as a support. The protective film serves as a protective layer to prevent damage to the resist, but is not limited thereto. The photosensitive resin layer may use the same components as the liquid type solder resist composition.

In addition, when the solder resist is a film type, it is difficult for air bubbles to be mixed in between the substrate and the solder resist layer, and the flatness of the film is excellent so that light emitting diodes (LEDs) can be mounted efficiently, and it is preferable in that it has high resolution.

The solder resist is applied in order to form, for example, a solder resist layer such as wiring boards, circuit boards, etc. In particular, a dry film solder resist is preferred.

The functional layer can be patterned by a photolithography method in order to form a metal layer pattern so that it is only partially covered. Accordingly, the light emitting diodes (LEDs) can be patterned after applying the light emitting diodes (LEDs) on the metal layer pattern in a form suitable for mounting light emitting diodes (LEDs). The specific method of photolithography is not particularly limited, but the content described in the method for manufacturing an optical laminate below may be applied without limitation.

The thickness of the functional layers 60 laminated on the metal layer 10 may be 1 μm to 3 mm.

As the light emitting diodes (LEDs) 70 of the present disclosure, publicly-known light emitting diodes (LEDs) may be applied without limitation.

### <Method for Manufacturing Optical Laminate>

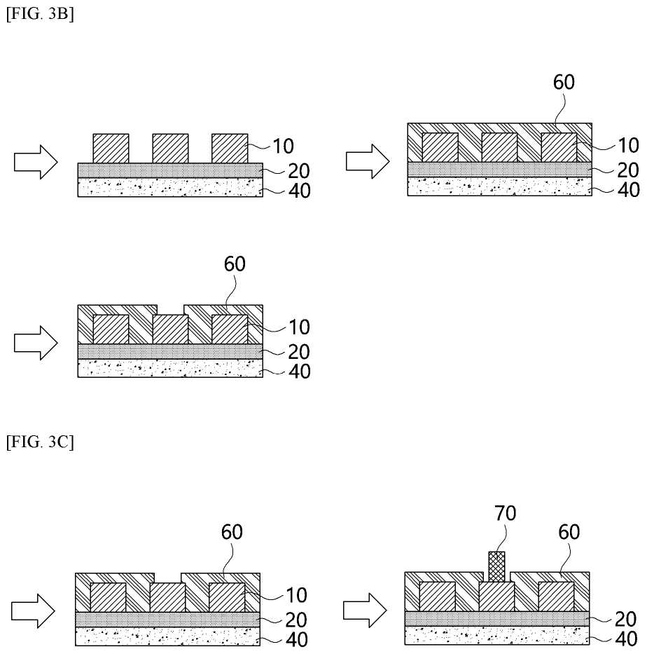

FIGS. 3A and 3B are views showing a method for manufacturing an optical laminate according to one embodiment of the present disclosure.

Referring to FIGS. 3A and 3B, the method for manufacturing an optical laminate according to one embodiment of the present disclosure may include steps of: preparing a metal thin film including a silicone-based pressure-sensitive adhesive layer 20 formed on one surface of a metal layer 10, and including a first protective film 30-1 provided on one surface of the silicone-based pressure-sensitive adhesive layer 20 and a second protective film 30-2 provided on the other surface of the metal layer 10; peeling off the first protective film 30-1 of the metal thin film; bonding the metal thin film so that the pressure-sensitive adhesive layer 20 is disposed on one surface of a glass substrate 40; peeling off the second protective film 30-2 of the metal thin film; patterning the metal layer 10 to form a metal layer pattern; and forming a functional layer 60 on a portion where a pattern of the metal layer 10 is not formed.

Specifically, the step of peeling off the first protective film provided on the metal thin film may be peeling off the first protective film 30-1 disposed on the bottom surface of the pressure-sensitive adhesive layer 20 of the metal thin film.

The protective film 30 may be provided to protect the surface of the metal layer 10 and/or the pressure-sensitive adhesive layer 20 from the outside, and for example, the protective film 30 may be provided in forms of a first protective film 30-1 formed on one surface of the pressure-sensitive adhesive layer 20 in order to protect the surface of the pressure-sensitive adhesive layer 20 and a second protective film 30-2 formed on one surface of the metal layer 10 in order to protect the surface of the metal layer 10.

In one embodiment, the protective film may be used as a single-layer structure which is formed in one layer as shown in FIG. 2, but is not limited thereto, and may also be used as a multi-layer structure in which one or more protective films are continuously laminated.

In one embodiment, the protective film 30 may be one in which a second protective film 30-2 and a first protective film 30-1 are laminated on one surface of the metal layer 10 and the pressure-sensitive adhesive layer 20 using a laminator, respectively.

The protective film 30 is not particularly limited as long as it is for protecting the surface of the metal layer 10 and/or the pressure-sensitive adhesive layer 20, and it may include, for example, one or more selected from the group consisting of polyethylene terephthalate (PET), polyethylene isophthalate (PEI), polyethylene naphthalate (PEN), polybutylene terephthalate (PBT), diacetyl cellulose, triacetyl cellulose (TAC), polycarbonate (PC), polyethylene (PE), polypropylene (PP), polymethyl acrylate (PMA), polyimide (PI), polymethyl methacrylate (PMMA), polyethyl acrylate (PEA), polyethyl methacrylate (PEMA), and cyclic olefin polymers (COP). In terms of ease of acquisition and processing convenience, polyethylene terephthalate (PET), triacetyl cellulose (TAC), polycarbonate (PC), polyimide (PI), and cyclic olefin polymers (COP) may be preferably used.

The thickness of the protective film 30 is not particularly limited and may be, for example, 10 μm to 200 μm.

Meanwhile, an example of the metal thin film described above includes a metal thin film having a protective film 30 provided on one surface of the metal layer 10 and the pressure-sensitive adhesive layer 20, respectively, but is not limited thereto. For example, the metal thin film may include only one of a protective film formed on one surface of the metal layer and a protective film formed on one surface of the pressure-sensitive adhesive layer.

The step of peeling off the first protective film provided on the metal thin film may be peeling off a first protective film 30-1 disposed on the bottom surface of the pressure-sensitive adhesive layer 20 of the metal thin film.

Peeling of the first protective film 30-1 may be appropriately performed within a range that does not impair the purpose of the present disclosure, and a method used in the peeling process of a conventional release film may also be used.

The step of bonding the metal thin film so that the pressure-sensitive adhesive layer is disposed on one surface of the glass substrate may be bonding the surface of the pressure-sensitive adhesive layer 20 exposed to the outside as the first protective film 30-1 is peeled off to one surface of the glass substrate 40.

Bonding of the pressure-sensitive adhesive layer 20 and the glass substrate 40 may be appropriately performed within a range that does not impair the purpose of the present disclosure, and they may be bonded using, for example, a laminator or the like.

The step of peeling off the second protective film provided on the metal thin film may be peeling off a second protective film 30-2 disposed on the top surface of the metal layer 10 of the metal thin film.

Peeling of the second protective film 30-2 may be performed by substantially the same method as peeling of the first protective film 30-1.

Meanwhile, the method for manufacturing an optical laminate of FIG. 3 described above is explained by taking the method for manufacturing an optical laminate using the metal thin film as an example, but is not necessarily limited thereto.

For example, in another embodiment of the present disclosure, when the metal thin film is not provided with the second protective film 30-2, the step of peeling off the second protective film provided on the metal thin film may be omitted.

The step of forming the pattern of the metal layer 10 of the optical laminate according to one embodiment of the present disclosure may include steps of: forming a photoresist pattern 50 on one surface of the metal layer 10; etching an exposed region of the metal layer 10 by the photoresist pattern; and peeling off the photoresist pattern.

Specifically, the step of forming a photoresist pattern 50 on one surface of the metal layer 10 may include a process of applying a photoresist pattern forming composition to a metal layer 10 by spin coating, slit coating, inkjet printing, etc., a process of drying and heat-treating the applied photoresist pattern forming composition to form a photoresist film, and a process of selectively exposing and developing the photoresist film to dissolve and remove the photoresist film corresponding to the exposed or non-exposed region, thereby forming a photoresist pattern 50.

The step of forming the photoresist pattern 50 may be performed by a publicly-known method, and detailed contents will be omitted.

The step of etching the exposed region of the metal layer 10 by the photoresist pattern 50 is not particularly limited and may be performed by a dry etching process or a wet etching process.

In one embodiment, the wet etching process may be performed using an etchant containing one or more selected from the group consisting of nitric acid, phosphoric acid, and acetic acid. As described above, since the pressure-sensitive adhesive layer 20 is characterized in that it contains a silicone-based pressure-sensitive adhesive, it has excellent chemical resistance to an etchant containing one or more selected from the group consisting of nitric acid, phosphoric acid, and acetic acid. Therefore, when the etching process is performed by wet etching using an etchant containing one or more selected from the group consisting of nitric acid, phosphoric acid, and acetic acid, not only is the etching performance to the metal layer 10 excellent, but also, even if the pressure-sensitive adhesive layer 20 located at the bottom of the metal layer 10 is exposed to the etchant, no damage (physical/chemical damage and white clouding phenomenon) to the pressure-sensitive adhesive layer 20 may occur.

The dry etching process or wet etching process may be performed by a publicly-known method, and detailed contents will be omitted.

The step of peeling off the photoresist pattern may be performed using a method of immersing the substrate on which the resist pattern 50 is formed in a resist stripper, a method of spraying the stripper onto the relevant substrate, or the like. Further, in this case, physical treatments such as irradiation of ultrasonic waves or contact with a brush that rotates or swings side to side may be used together.

In one embodiment, the resist peeling conditions may include a temperature of about 15° C. to 100° C., preferably 30° C. to 70° C., and an immersion or spray time of preferably about 1 minute to 20 minutes, but are not limited thereto, and may be appropriately modified according to the user's needs.

In one embodiment, after the resist stripper treatment, a cleaning treatment may be additionally performed in order to remove the stripper remaining on the substrate. The cleaning treatment may be performed in the same manner as in the stripping process described above except that water or isopropyl alcohol is used instead of the stripper.

In one embodiment of the present disclosure, the step of forming the functional layer 60 may be a step of forming any one solder resist layer of a liquid type and a film type, preferably a step of forming a film type solder resist layer.

The method of forming the functional layer 60 is not particularly limited, but it may be a method of manufacturing any one solder resist layer of the liquid type and the film type by a publicly-known method.

### <Transparent Display and Manufacturing Method>

The present disclosure includes a transparent display manufactured using the optical laminate of the present disclosure described above and a method for manufacturing the same.

Specifically, the present disclosure relates to the above-described optical laminate; and a transparent display including light emitting diodes (LEDs). FIG. 2 is a view showing one embodiment of a transparent display of the present disclosure. Referring to FIG. 2, the transparent display of the present disclosure is a form in which light emitting diodes (LEDs) 70 are formed in a portion of the patterned metal layer 10 of the optical laminate where the functional layer 60 is not formed. More specifically, the portion of the patterned metal layer 10 of the metal thin film substrate where the functional layer 60 is not formed may further include a solder layer (not shown), and the light emitting diodes (LEDs) 70 may be mounted through the solder layer. The arrangement spacing or density of the light emitting diodes (LEDs) is not particularly limited, but may be arranged in a lattice form. In this case, the top, bottom, left, and right spacings may be 1 to 50 mm, and the spacings of the plurality of light emitting diodes (LEDs) may be the same as or different from each other. When forming the light emitting diodes (LEDs) on the metal thin film substrate of the present disclosure, there is an advantage as a transparent display capable of transmitting and reproducing images on a substrate having transparency.

In addition, the transparent display manufacturing method of the present disclosure includes a step of mounting light emitting diodes (LEDs) on the optical laminate described above. FIG. 3C relates to a method for manufacturing a transparent display according to one embodiment of the present disclosure, and is a view showing the step of mounting light emitting diodes (LEDs) 70 on the portion of the patterned metal layer 10 of the optical laminate of the present disclosure where the functional layer 60 is not formed.

In the present disclosure, the method of forming the light emitting diodes (LEDs) on the optical laminate of the present disclosure may include a method of surface mounting the element by performing soldering (SMT: Surface Mount Technology), and the like, but is not limited thereto.

The present disclosure includes a structure and method that further include an overcoat layer covering the top of the light emitting diodes (LEDs) or the entire transparent display. The overcoat layer may include conventionally known materials without limitation, and its thickness is also not particularly limited as long as it is at a level commonly applied to those skilled in the art.

As the optical laminate of the present disclosure exhibits the above-described characteristics, it can be suitably used in display devices requiring large areas and low resistance, and in terms of particularly excellent heat resistance and reliability in high temperature and high humidity environments, it has the advantage of capable of being particularly suitably used in devices that may be exposed to the external environment for a long time such as transparent displays, etc.

Hereinafter, an Experimental Example including specific Examples and Comparative Examples are presented to aid understanding of the present disclosure, but the Experimental Example including specific Examples and Comparative Examples is only illustrative of the present disclosure and does not limit the scope of the appended claims, and it is obvious to those skilled in the art that various changes and modifications to the Examples are possible within the scope of the present disclosure and the scope of the technical spirit, and it is also natural that such changes and modifications fall within the scope of the appended claims. In addition, “%” and “part” indicating the content in the following are based on weight unless specifically stated.

### EXAMPLES AND COMPARATIVE EXAMPLES: MANUFACTURING OF OPTICAL LAMINATE

### Example 1

After adding 4 kg of 99% toluene to 10 kg of a silicone-based pressure-sensitive adhesive (DOWSIL™ 96-083 Silicone Adhesive Kit, DOW; solid content of 70%) to prepare a composition with a 50% silicone-based pressure-sensitive adhesive content, the composition was stirred with a stirrer (5 horsepower), and then 0.5 g of an anchorage (SYL-OFF™ SL-9250, DOW) as an additive, 0.8 g of a crosslinker (SYL-OFF™ 7678, DOW), and 1 g of a platinum catalyst were further mixed to prepare an pressure-sensitive adhesive layer composition.

Thereafter, the pressure-sensitive adhesive layer composition was applied onto one surface of a copper metal substrate (surface roughness (Rz) of 9.0 μm) with a thickness of 30 m by the gravure coating method, and then cured at 150° C. for 2 minutes to manufacture a metal thin film in which a silicone-based pressure-sensitive adhesive layer with a thickness of 10 m was formed on one surface of the metal substrate.

Thereafter, the pressure-sensitive adhesive layer of the metal thin film was allowed to be disposed on one surface of a glass substrate with a thickness of 2 mm, and then the metal thin film was bonded thereto using a sheet to sheet method to laminate a metal layer.

Thereafter, a metal layer pattern was formed by patterning the metal layer by the photolithography method as shown in FIG. 3.

The optical laminate of Example 1 was manufactured by forming a functional layer with a solder resist on a portion on the pressure-sensitive adhesive layer where the metal layer pattern was not formed, as shown in FIG. 1. Specifically, a solder resist liquid solution was prepared by mixing a monomer (ELVAROY™, manufacturer: DOW), a binder (VORAMER™, manufacturer: DOW), and a photoinitiator (Irgacure 907, manufacturer: Ciba Specialty Chemicals) at a ratio of 5:3:2, and mixing a PGMEA solvent with the mixture of the monomer, the binder, and the photoinitiator at a ratio of 5.5:4.5. This was applied uniformly on the top of the film and then dried in an oven at 85° C. for 6 minutes to manufacture a transparent dry film solder resist. At this time, the thickness of the functional layer was 50 μm.

### Example 2

An optical laminate was manufactured in the same manner as in Example 1 except that the functional layer was manufactured using a solder resist liquid solution prepared by mixing a monomer (ELVAROY™, manufacturer: DOW), a binder (VORAMER™, manufacturer: DOW), and a photoinitiator (Irgacure 907, manufacturer: Ciba Specialty Chemicals) at a ratio of 5:3:2, and mixing a PGMEA solvent with the mixture of the monomer, the binder, and the photoinitiator at a ratio of 8:2.

### Example 3

An optical laminate was manufactured in the same manner as in Example 1 except that a copper metal substrate with a surface roughness (Rz) of 0.9 μm was used.

### Comparative Example 1

An optical laminate was manufactured in the same manner as in Example 1 except that the functional layer was not formed.

### Comparative Example 2

An optical laminate was manufactured in the same manner as in Example 3 except that the functional layer was not formed.

### Comparative Example 3

An optical laminate was manufactured in the same manner as in Example 1 except that the following transparent photosensitive resin composition instead of the transparent dry film solder resist was applied using a comma coater and then dried at 120° C. for 5 minutes to form a 5 μm thick negative transparent photosensitive resin composition layer.

The transparent photosensitive resin composition layer was prepared by dissolving 16 g of an acrylate resin with a weight average molecular weight of 10,100 g/mol, an acid value of 77 mg KOH/g, and an acrylic reaction group ratio of 30 mol %, 7.5 g of dipentaerythritol hexaacrylate, 1 g of OXE-02 from BASF as a photoinitiator, and 0.5 g of Glide-410 as a surfactant in 75 g of propylene glycol monomethyl ether acetate (PGMEA) and then filtering the dissolved solution with a 0.1 μm-sized filter.

The transparent photosensitive resin composition layer applied on a copper foil pattern was selectively removed by irradiating an amount of light of 100 mJ/cm² using a parallel light exposure machine (Karl Suss MA-8) on the back of the surface on which the transparent photosensitive resin composition layer is provided, and then developing the transparent photosensitive resin composition layer.

### Experiment Example

### (1) Transmittance and Haze Evaluation

For the optical laminates of Examples and Comparative Examples, transmittance and haze were measured using a haze meter HM-150N (Murakami), and the results are shown in Table 1 below.

### (2) Evaluating Whether Air Bubbles are Generated or not

For the optical laminates of Examples and Comparative Examples, the ratio of air bubble generation length to the entire wiring length was measured, and the results are shown in Table 1 below according to the following criteria.
◯: 0.5% or less
x: 1% or more

### (3) Reliability Evaluation

For the optical laminates of Examples and Comparative Examples including functional layers, whether there was physical damage to the film or not was evaluated at the boundary of the functional layer near the wiring, and the results are shown in Table 1 below according to the following criteria.
◯: There was no physical opening of the film at the boundary of the functional layer near the wiring

x: Physical opening of the film was observed at the boundary of the functional layer near the wiring

(4) Haze after Long-Term Storage

For the optical laminates of Examples and Comparative Examples, the haze was measured according to the method of (1) above after being left at a high temperature condition of 90° C. for 500 hours, and the results are shown in Table 1 below according to the following criteria.
◯: Yellowish was not observed
x: Yellowish was observed

TABLE 1

| | | | | Comparative | Comparative | Comparative |
|---|---|---|---|---|---|---|
| Classification | Example 1 | Example 2 | Example 3 | Example 1 | Example 2 | Example 3 |
| Transmittance (%) | 80.9 | 80.9 | 88.4 | 78.6 | 85.3 | 80.9 |
| Haze | 17.5 | 17.5 | 1.5 | 79.1 | 12.5 | 18.1 |
| Whether air | ∘ | ∘ | ∘ | x | x | x |
| bubbles are | | | | | | |
| generated or | | | | | | |
| not | | | | | | |
| Reliability | ∘ | ∘ | ∘ | x | x | x |
| evaluation | | | | | | |
| Haze after | ∘ | ∘ | ∘ | x | x | x |
| long-term | | | | | | |
| storage | | | | | | |

Referring to Table 1, it can be confirmed that the optical laminates of the Examples including the functional layer of the present disclosure had excellent transmittances, significantly low hazes, and improved reliability by reducing the generation of air bubbles compared to those of the Comparative Examples that did not include the functional layer of the present disclosure.

That is, when comparing the optical laminates of Example 1 and Comparative Example 1 using metal substrates with the same surface roughness (Rz) and comparing the optical laminates of Example 3 and Comparative Example 2, it can be confirmed that the optical laminates of the Examples including the functional layer of the present disclosure had excellent transmittances and significantly low hazes compared to those of the Comparative Examples that did not include the functional layer of the present disclosure. In particular, in the case of Comparative Example 3, which used a resin type as the functional layer, it was confirmed that the haze increased due to yellowish color due to long-term reliability or when left outdoors for a long period of time.

Further, in the case of Comparative Example 3, a physical opening phenomenon of the film was observed at the boundary of the functional layer near the wiring. This is because the boundary along the edge of the wiring is exposed when the back surface is exposed in order to form a functional layer, and this means that the possibility of damage to the corresponding area during external exposure or heating is greatly increased, thereby greatly reducing reliability.

### EXPLANATION OF REFERENCE NUMERALS

10: Metal layer
20: Pressure-sensitive adhesive layer
30: Protective film
40: Glass substrate
50: Photoresist pattern
60: Functional layer
70: Light emitting diodes (LEDs)

1. An optical laminate comprising:
a glass substrate;
a pressure-sensitive adhesive layer formed on one surface of the glass substrate;
a metal layer pattern formed on one surface of the pressure-sensitive adhesive layer; and
a functional layer provided on a portion on one surface of the pressure-sensitive adhesive layer on which the metal layer pattern is not formed,
wherein the pressure-sensitive adhesive layer contains a silicone-based pressure-sensitive adhesive, and the functional layer includes a solder resist layer.

2. The optical laminate of claim 1, wherein the functional layer is provided to cover the entirety or a portion of the metal layer pattern.

3. The optical laminate of claim 1, wherein the metal layer has a thickness of 3 μm to 120 μm.

4. The optical laminate of claim 1, wherein the metal layer contains one or more selected from the group consisting of copper (Cu), aluminum (Al), nickel (Ni), chromium (Cr), silver (Ag), iron (Fe), gold (Au), cobalt (Co), titanium (Ti), and tungsten (W).

5. The optical laminate of claim 1, wherein the pressure-sensitive adhesive layer has a thickness of 5 μm to 50 μm.

6. The optical laminate of claim 1, wherein the optical laminate does not include a separate member between the metal layer and the pressure-sensitive adhesive layer.

7. The optical laminate of claim 1, wherein the pressure-sensitive adhesive layer has an adhesive force with a glass substrate of 5B or more.

8. A transparent display comprising:
the optical laminate of claim 1; and
light emitting diodes.

9. The transparent display of claim 8, further comprising a transparent cover at the outermost portion corresponding to the glass substrate of the optical laminate.

10. The transparent display of claim 9, wherein the transparent cover is one or more selected from glass, wired sheet glass, colored glass, magic mirror, and holographic glass.

11. The transparent display of claim 10, wherein when the transparent cover is glass, it further includes one or more selected from wired sheet glass, colored glass, magic mirror, and holographic glass.

12. A method for manufacturing an optical laminate, comprising steps of.
preparing a metal thin film comprising a silicone-based pressure-sensitive adhesive layer formed on one surface of a metal layer, and including a first protective film provided on one surface of the silicone-based pressure-sensitive adhesive layer and a second protective film provided on the other surface of the metal layer;
peeling off the first protective film of the metal thin film;
bonding the metal thin film so that the pressure-sensitive adhesive layer is disposed on one surface of a glass substrate;
peeling off the second protective film of the metal thin film;
patterning the metal layer to form a metal layer pattern; and
forming a functional layer on a portion where the metal layer pattern is not formed, wherein the functional layer includes a solder resist layer.

13. The method of claim 12, wherein the step of forming the metal layer pattern comprises steps of:
forming a photoresist pattern on one surface of the metal layer;
etching an exposed region of the metal layer by the photoresist pattern; and
peeling off the photoresist pattern.

14. The method of claim 12, wherein damage to the lower pressure-sensitive adhesive layer does not occur in the etching step.
